(19) United States
(12) Patent Application Publication
(10) Pub. No.: US 2024/0304763 A1
(43) Pub. Date: Sep. 12, 2024

(54) DISPLAY PANEL

(71) Applicant: TCL TECHNOLOGY GROUP CORPORATION, Huizhou, Guangdong (CN)

(72) Inventor: Wenjun HOU, Huizhou, Guangdong (CN)

(21) Appl. No.: 18/263,356

(22) PCT Filed: Dec. 30, 2021
(86) PCT No.: PCT/CN2021/143270

§ 371 Date: Jul. 28, 2023

(30) Foreign Application Priority Data
Apr. 27, 2021 (CN) 202110457447.1

(51) Int. Cl. H01L 33/50; H01L 25/075; H01L 33/28; H01L 33/56

(52) U.S. Cl. CPC H01L 33/502; H01L 25/0753; H01L 33/28; H01L 33/56

(57) ABSTRACT

Embodiments of the present application disclose a display panel. The display panel comprises an array substrate and a light-emitting structure; the array substrate comprises a light conversion layer, and the light conversion layer is configured to convert other light into red light; the light-emitting structure is disposed on the array substrate, and the light-emitting structure emits white light.

### PRIORITY

This application claims priority to Chinese Patent Application No. 202110457447.1, filed on Apr. 27, 2021, entitled “DISPLAY PANEL”, which is incorporated herein by reference in its entirety.

### TECHNICAL FIELD

The present application relates to a field of display technology, and more particularly, to a display panel.

### BACKGROUND

With rapid development of light-emitting diode (LED) technology and gradual improvement of light efficiency of the light-emitting diodes, applications of the light-emitting diodes are more and more extensive. Currently, white light-emitting diode devices are designed to emit white lights by mixing materials of red, green, and blue color in different proportions. The materials of red, green, and blue color can be processed into a film by solution processing, spin coating or ink-jet printing. Then the film can be integrated with the light-emitting diode device to function as an effective exciton radiation combination center.

The white light-emitting diode devices require injection of electrons and holes in operation, and a simplest structure of the white light-emitting diode device includes a cathode, an electron transport layer, a light-emitting layer, a hole transport layer, and an anode. In the white light-emitting diode device, the light-emitting layer is sandwiched between the electron transport layer and the hole transport layer. When a forward bias voltage is applied to both ends of the light-emitting diode device, electrons and holes enter the light-emitting layer through the electron transport layer and the hole transport layer, respectively, and the electrons and holes are combined to emit lights in the light-emitting layer.

However, the white light-emitting diode currently has a low color rendering index, as such, the performance on color reproduction is poor. Thus, there is a need for a white light-emitting diode device having a high color rendering index.

### SUMMARY OF THE DISCLOSURE

### Technical Problem

Embodiments of the present application provide a display panel to solve a problem of a low color rendering index of a white display panel.

### TECHNICAL SOLUTIONS OF THE DISCLOSURE

### Summary of the Technical Solutions

An embodiment of the present application provides a display panel including:
an array substrate, wherein the array substrate includes a light-converting layer, and the light-converting layer is configured to convert other lights into red light; and
a light-emitting structure disposed on the array substrate, wherein the light-emitting structure emits white lights.

In some embodiments of the present application, the array substrate further includes a substrate, and a transistor layer disposed on the substrate; wherein the light-converting layer is doped with red light-emitting particles, and the light-converting layer is disposed between the transistor layer and the light-emitting structure.

In some embodiments of the present application, doping concentration of the red light-emitting particles in the light-converting layer ranges from 5% to 35%.

In some embodiments of the present application, each of the red light-emitting particles is in a shell-coated structure, and a shell layer of the shell-coated structure covers a core layer of the shell-coated structure.

In some embodiments of the present application, a material of the core layer includes at least one of CdSe, CdZnSe, InP, and ZnSe.

In some embodiments of the present application, a material of the shell layer includes at least one of CdS and ZnS.

In some embodiments of the present application, the array substrate further includes a substrate, the light-emitting structure is disposed on the substrate, and the light-converting layer is disposed on a side of the substrate away from the light-emitting structure.

In some embodiments of the present application, the display panel further includes a protective layer, and the protective layer is disposed on a side of the light-converting layer away from the light-emitting structure.

In some embodiments of the present application, the light-converting layer has a thickness ranging from 50 nm to 3000 nm.

In some embodiments of the present application, each of the red light-emitting particles has a particle diameter ranging from 7 nm to 8 nm.

In some embodiments of the present application, a material of the light-converting layer is selected from polyimide, polymethyl methacrylate, silicone resin, and epoxy resin.

In some embodiments of the present application, the light-emitting structure includes a first light-emitting unit, a second light-emitting unit, and a third light-emitting unit sequentially stacked; wherein the first light-emitting unit, the second light-emitting unit, and the third light-emitting unit include a red light-emitting unit, a blue light-emitting unit, and a green light-emitting unit; wherein the first light-emitting unit, the second light-emitting unit, and the third light-emitting unit emit lights of different colors respectively.

In some embodiments of the present application, the display panel further includes a first transparent conductive layer and a second transparent conductive layer;
the light-emitting structure further includes a first electrode layer and a second electrode layer;
the first light-emitting unit includes a first hole injection layer, a first hole transport layer, a first light-emitting layer, and a first electron transport layer sequentially stacked on the first electrode layer;
the second light-emitting unit includes a second hole injection layer, a second hole transport layer, a second light-emitting layer, and a second electron transport layer sequentially stacked on the first transparent conductive layer;
the third light-emitting unit includes a third hole injection layer, a third hole transport layer, a third light-emitting layer, and a third electron transport layer sequentially stacked on the second transparent conductive layer; and
the second electrode layer is disposed on a side of the third electron transport layer away from the substrate.

In some embodiments of the present application, a material each of the first light-emitting layer, the second light-emitting layer, and the third light-emitting layer has a core-shell structure, and a shell layer of the core-shell structure covers a core layer of the core-shell structure, wherein a material of the core layer includes one of CdZnSe, ZnSe, InP, and CdSe, and a material of the shell layer includes one or a combination of CdS and ZnS.

In some embodiments of the present application, materials of the first transport layer, the second electron transport layer, and the third electron transport layer include at least one of Zn_{0.98}Al_{0.02}O, Zn_{0.9}Mg_{0.05}Li_{0.05}O, Zn_{0.9}Mg_{0.1}O, and Zn_{0.88}Mg_{0.12}O.

In some embodiments of the present application, the display panel further includes a first electrode layer, the transistor layer is disposed on the substrate, the light-converting layer is disposed on the transistor layer, the first electrode layer is disposed on the light-converting layer, and the light-emitting structure is disposed on the first electrode layer.

In some embodiments of the present application, the display panel further includes an organic flat layer, and the organic flat layer is disposed between the light-converting layer and the first electrode layer.

In some embodiments of the present application, the display panel further includes an organic flat layer and a first electrode layer, the light-converting layer is disposed on the protective layer, the substrate is disposed on the light-converting layer, the transistor layer is disposed on the substrate, the organic flat layer is disposed on the transistor layer, the first electrode layer is disposed on the organic flat layer, and the light-emitting structure is disposed on the first electrode layer.

In some embodiments of the present application, the display panel further includes an organic flat layer and a first electrode layer, the light-converting layer is disposed on the protective layer, the substrate is disposed on the light-converting layer, the transistor layer is disposed on the substrate, the organic flat layer is disposed on the transistor layer, the first electrode layer is disposed on the organic flat layer, and the light-emitting structure is disposed on the first electrode layer.

In some embodiments of the present application, the protective layer includes an organic protective layer and an inorganic protective layer; a material of the organic protective layer is selected from polycarbonate, polyimide, and polymethyl methacrylate; and a material of the inorganic protective layer is selected from silicon dioxide, silicon nitride, silicon oxynitride, and aluminum trioxide.

### BENEFICIAL EFFECT OF THE DISCLOSURE

### Beneficial Effect

An embodiment of the present application discloses a display panel including an array substrate and a light-emitting structure. The array substrate includes a light-converting layer for converting other lights into red lights, the light-emitting structure is disposed on the array substrate, and the light-emitting structure emits white lights. In the present application, by providing the light-converting layer, the color rendering index of the display panel is improved, and the performance of the display panel is improved.

### BRIEF DESCRIPTION OF THE DRAWINGS

### Description of the Drawings

In order to explain the technical solution in the embodiments of the present application more clearly, reference is now made briefly to the accompanying drawings required for the description of the embodiments. It should be understood that the accompanying drawings in the following description are merely some of the embodiments of the present application, and other drawings may be made to a skilled person in the art based on the accompanying drawings without inventive effort.

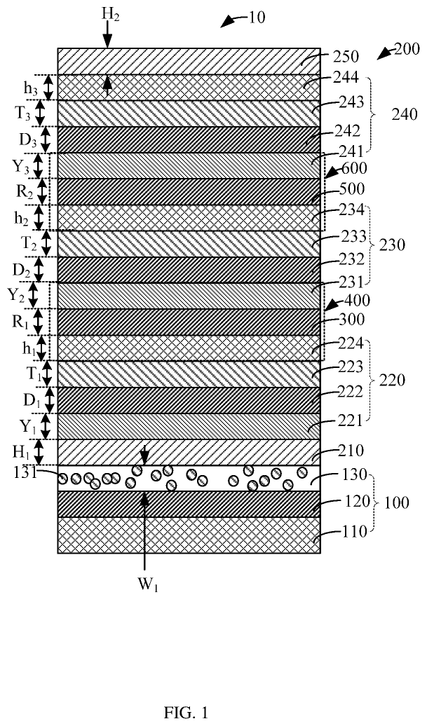

FIG. 1 is a schematic diagram of a first structure of a display panel according to an embodiment of the present application.

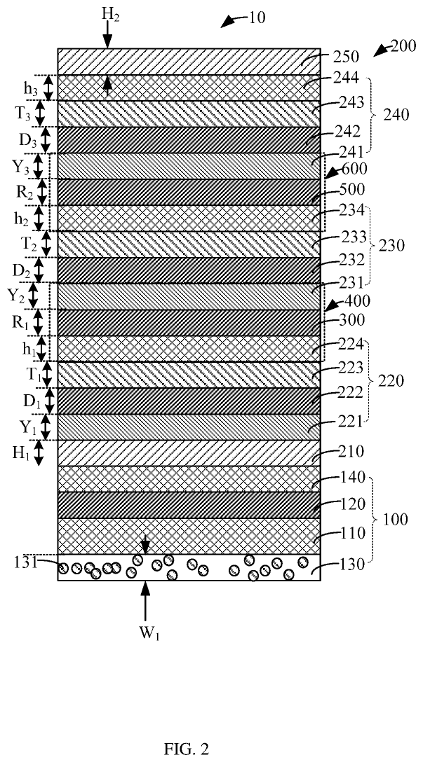

FIG. 2 is a schematic diagram of a second structure of a display panel according to an embodiment of the present application.

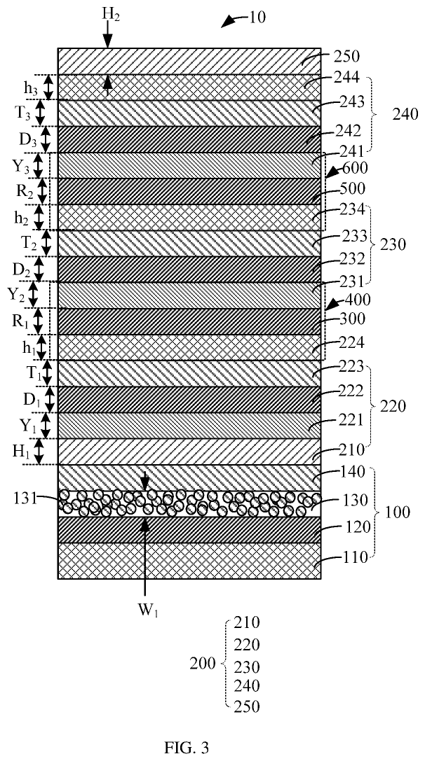

FIG. 3 is a schematic diagram of a third structure of a display panel according to an embodiment of the present application.

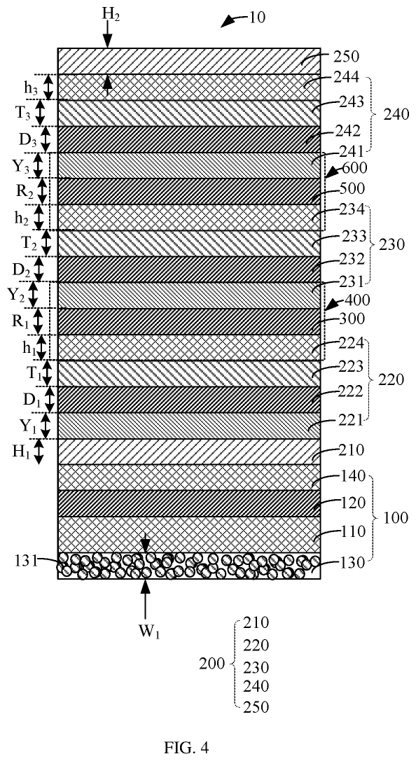

FIG. 4 is a schematic diagram of a fourth structure of a display panel according to an embodiment of the present application.

### DETAILED DESCRIPTION OF THE EMBODIMENTS

In the following, the technical solutions in the embodiments of the present application are clearly and completely described in connection with the accompanying drawings in the embodiments of the present application. It should be understood that the described embodiments are merely a part of the embodiments of the present application, rather than all the embodiments. Based on the embodiments in the present application, all other embodiments obtained by a person skilled in the art without inventive effort are within the scope of the present application. Furthermore, it should be understood that the specific embodiments described herein are for purposes of illustration and explanation only, and are not intended to limit the application. In the present application, without stating to the contrary, the positional terms such as “on” and “below” generally refer to a position located on and below the device in actual use and working state, specifically refer to the direction shown in the accompanying drawings. Moreover, the terms “in” and “out” are for the outline of the device.

The embodiment of the application provides a display panel. Detailed descriptions are given below.

Referring to FIG. 1, FIG. 1 is a schematic diagram of a first structure of a display panel according to an embodiment of the present application. The present application provides a display panel 10. The display panel 10 includes an array substrate 100 and a light-emitting structure 200.

The array substrate 100 includes a substrate 110, and a transistor layer 120 disposed on the substrate 110. The array substrate 100 includes a light-converting layer 130. The light-converting layer 130 is configured to convert other lights into red lights. The light-converting layer 130 is doped with red light-emitting particles 131. Specifically, the light-converting layer 130 is provided on a side of the transistor layer 120 away from the substrate 110.

In an embodiment, the substrate 110 may be a rigid substrate or a flexible substrate. The rigid substrate may be a glass substrate. The flexible substrate may be a polyimide substrate.

In an embodiment, a thickness W₁ of the light-converting layer 130 ranges from 50 nm to 3000 nm.

In an embodiment, the thickness W₁ of the light-converting layer 130 ranges from 50 nm to 3000 nm, specifically, the thickness W₁ of the light-converting layer 130 may be 50 nm, 60 nm, 200 nm, 400 nm, 900 nm, 1600 nm, 1800 nm, 2000 nm, 2200 nm, 2400 nm, 2600 nm, or 3000 nm, and the like. In the present embodiment, the thickness W₁ of the light-converting layer 130 is 200 nm.

In the present application, by providing the light-converting layer 130 with the thickness W₁ ranging from 50 nm to 3000 nm, the light-converting effect of the light-converting layer 130 is improved. In a case that the thickness W₁ of the light-converting layer 130 is provided less than 50 nm, the light-converting efficiency of the light-converting layer 130 is reduced, and the color rendering index of the display panel 10 is affected. In a case that the thickness W₁ of the light-converting layer 130 is provided greater than 3000 nm, colors of all lights in an addition to red lights are converted into red, and the display panel 10 cannot emit white lights.

In an embodiment, the material of the light-converting layer 130 is selected from polyimide, polymethyl methacrylate, silicone resin, and epoxy resin. In this embodiment, the material of the light-converting layer 130 is polymethyl methacrylate.

In the present application, the light-converting layer 130 is formed by using polyimide, polymethyl methacrylate, silicone resin, and epoxy resin, so that the light-converting layer 130 functions as an organic flat layer of the white display panel 10 to flatten the film layer structure in the white display panel 10, thereby avoiding damage to the structures in the white display panel during subsequent processing or use.

In an embodiment, doping concentration of the red light-emitting particles 131 in the light-converting layer 130 ranges from 5% to 35%. Specifically, the doping concentration of the red light-emitting particles 131 in the light-converting layer 130 may be 5%, 7%, 10%, 14%, 18%, 20%, 25%, 28%, 30%, 32%, or 35%, or the like. In the present embodiment, the doping concentration of the red light-emitting particles 131 in the light-converting layer 130 is 26%.

In the present application, the doping concentration of the red light-emitting particles 131 in the light-converting layer 130 ranges from 5% to 35%, so that the color rendering index of the display panel 10 is increased. In a case that the doping concentration of the red light-emitting particles 131 in the light-converting layer 130 is provided less than 5%, the light-converting layer 130 requires a sufficient thickness to ensure the color rendering index of the display panel 10, however, the increased thickness of the film layer of the display panel is disadvantageous to the lightweight design. In a case that the doping concentration of the red light-emitting particles 131 in the light-converting layer 130 is provided greater than 35%, the red light-emitting particles 131 are needed to generate a phase separation from the organic matters therein, just to ensure the color rendering index of the display panel 10.

Phase separation means that when external conditions such as temperature, pressure, and the like are changed, the multi-component system sometimes separates into several phases having different components and structures.

In an embodiment, the red light-emitting particle 131 has a particle diameter ranging from 7 nm to 8 nm. Specifically, the red light-emitting particle 131 may have a particle diameter of 7 nm, 7.2 nm, 7.3 nm, 7.4 nm, 7.5 nm, 7.6 nm, or 8 nm, and the like. In this embodiment, the red light-emitting particle 131 has a particle diameter of 7.5 nm.

In an embodiment, the red light-emitting particle 131 is a core-shell structure in which a shell layer covers a core layer. The band gap of the shell layer is greater than the band gap of the core layer.

In an embodiment, the material of the core layer is selected from InP, ZnSe, CdSe, and CdZnSe. The material of the shell layer is selected from CdS and ZnS. In this embodiment, the material of the core layer is InP, and the material of the shell layer is a combination of CdS and ZnS.

In the present application, the material of the core layer is selected from InP, CdZnSe, CdSe and ZnSe, the material of the shell layer is selected from CdS and ZnS, and the particle diameter of the red light-emitting particle 131 ranges from 7 nm to 8 nm, so that the red light-emitting particles emit red lights.

In the present application, by providing a core-shell structure to the red light-emitting particle 131, because the band gap of the shell layer is greater than the band gap of the core layer, the light-converting layer 130 expands the range of the photon collection spectrum while avoiding the influence of the defect of the core layer on the light emission of the light-converting layer 130. In addition, by adjusting the thickness of the shell layer, the coupling characteristics of the core layer can be prevented from being affected, thereby improving the stability of the display of the white display panel 10.

In an embodiment, the red light-emitting particle 131 has a photoluminescence wavelength ranging from 600 nm to 630 nm.

In an embodiment, the photoluminescence of the red light-emitting particle 131 has a full width at half maxima ranging from 40 nm to 90 nm. Specifically, the full width at half maxima of the photoluminescence of the red light-emitting particle 131 may be 40 nm, 56 nm, 68 nm, 79 nm, 83 nm, 90 nm, or the like. In the present embodiment, the full width at half maxima of the photoluminescence of the red light-emitting particle 131 is 80 nm.

Full width at half maxima refers to the width of the peak at half the height of the chromatographic peak. This is, a straight line parallel to a bottom of the peak through the midpoints of the peak to intersect both sides of the peak with two points, and full width at half maxima is a distance between the two points.

In the present application, a continuous spectrum having a wide full width at half maxima is provided, that is, the full width at half maxima of the photoluminescence of the red light-emitting particle 131 ranges from 40 nm to 90 nm. Thus, the color rendering index of the white display panel 10 is increased, and the performance of the display panel is further improved.

The principle of the photoluminescence mechanism is that the quantum dots are irradiated by external lights, so that the quantum dots obtain energy and generate excitations to emit lights.

In the present application, the light-converting layer 130 is doped with the red light-emitting particles 131, and the light-converting layer 130 can be used as an organic flat layer of the array substrate 100, so that the light-converting layer 130 provides a flatness while having a light-converting effect, thereby improving the conversion effect of the light-converting layer 130, improving the color rendering index of the white display panel 10, and further improving the performance of the white display panel 10.

The color rendering index refers to an effect of a light source to be measured on an appearance of a colored object, compared with a standard light source. That is, a degree of verisimilitude or reality of a color. A higher color rendering index of a light source indicates that the color of the object under the light source is closer to the true color of the object.

The light-emitting structure 200 is disposed on the array substrate 100, and emits white lights. Specifically, the light-emitting structure 200 is provided on a side of the light-converting layer 130 away from the substrate 110.

In an embodiment, the light-emitting structure 200 includes a first electrode layer 210. The first electrode layer 210 may be an anode or a cathode. In this embodiment, the first electrode layer 210 is an anode.

In an embodiment, the material of the first electrode layer 210 includes one or more of indium tin oxide, indium zinc oxide, zinc aluminum oxide, and indium gallium zinc oxide. In this embodiment, the material of the first electrode layer 210 is indium zinc oxide.

In an embodiment, the first electrode layer 210 has a thickness H₁ ranging from 50 nm to 1000 nm. Specifically, the thickness H₁ of the first electrode layer 210 may be 50 nm, 400 nm, 650 nm, 800 nm, 1000 nm, or the like. In this embodiment, the thickness H₁ of the first electrode layer 210 is 500 nm.

In an embodiment, the light-emitting structure 200 further includes a first light-emitting unit 220, a second light-emitting unit 230, and a third light-emitting unit 240 stacked sequentially. The first light-emitting unit 220, the second light-emitting unit 230, and the third light-emitting unit 240 include a green light-emitting unit, a blue light-emitting unit, and a red light-emitting unit. The first light-emitting unit 220, the second light-emitting unit 230, and the third light-emitting unit 240 emit lights of different colors respectively.

The first light-emitting unit 220, the second light-emitting unit 230, and the third light-emitting unit 240 may combine to emit white lights.

The first light-emitting unit 220 includes a first hole injection layer 221, a first hole transport layer 222, a first light-emitting layer 223, and a first electron transport layer 224, which are sequentially stacked on the first electrode layer 210.

In an embodiment, the material of the first hole injection layer 221 includes polyaniline, poly(3,4-ethylenedioxythiophene): polystyrene sulfonate, and polythiophene. In this embodiment, the material of the first hole injection layer 221 is polystyrene sulfonate.

In an embodiment, the first hole injection layer 221 has a thickness Y₁ ranging from 50 nm to 500 nm. Specifically, the thickness Y₁ of the first hole injection layer 221 may be 50 nm, 100 nm, 190 nm, 280 nm, 350 nm, 450 nm, 490 nm, 500 nm, or the like. In the present embodiment, the thickness Y₁ of the first hole injection layer 221 is 400 nm.

In an embodiment, the material of the first hole transport layer 222 includes one or more of 4,4′,4″-tris(carbazol-9-yl)triphenylamine, poly(N,N′-bis(4-butylphenyl)-N,N′-bis(phenyl)-benzidine), poly(9,9-dioctylfluorene-co-N-(4-butylphenyl)diphenylamine), polyvinylcarbazole, and 4,4′-bis(9-carbazole)biphenyl. In this embodiment, the material of the first hole transport layer 222 is 4,4′-bis(9-carbazole)biphenyl.

In an embodiment, the first hole transport layer 222 has a thickness D₁ ranging from 15 nm to 40 nm. Specifically, the thickness D₁ of the first hole transport layer 222 may be 15 nm, 18 nm, 30 nm, 33 nm, 36 nm, 40 nm, or the like. In this embodiment, the thickness D₁ of the first hole transport layer 222 is 19 nm.

In an embodiment, the first light-emitting layer 223 includes one of a red light-emitting layer, a green light-emitting layer, and a blue light-emitting layer. In this embodiment, the first light-emitting layer 223 is a blue light-emitting layer, that is, the first light-emitting unit 220 is a blue light-emitting unit.

In an embodiment, the material of the first light-emitting layer 223 is a core-shell structure in which a shell layer covers a core layer. The band gap of the shell layer is greater than the band gap of the core layer.

In an embodiment, the material of the core layer includes one of CdZnSe, ZnSe, InP, and CdSe. The material of the shell layer includes at least one of ZnS and CdS. In this embodiment, the material of the core layer is ZnSe, and the material of the shell layer is CdS.

In an embodiment, the material of the first light-emitting layer 223 has a particle diameter ranging from 1 nm to 2 nm. In this embodiment, the particle diameter of the material of the first light-emitting layer 223 is 2 nm.

In the present application, the material of the core layer is ZnSe, the material of the shell layer is CdS, and the particle diameter of the first light-emitting layer 223 ranges from 1 nm to 2 nm, so that the first light-emitting layer 223 emits blue lights.

In an embodiment, the first light-emitting layer 223 has a photoluminescence wavelength ranging from 465 nm to 480 nm.

In an embodiment, the first light-emitting layer 223 has a thickness T₁ ranging from 10 nm to 40 nm. Specifically, the thickness T₁ of the first light-emitting layer 223 may be 11 nm, 12 nm, 18 nm, 20 nm, 28 nm, 34 nm, 36 nm, 40 nm, or the like. In this embodiment, the thickness T₁ of the first light-emitting layer 223 is 34 nm.

In an embodiment, the material of the first electron transport layer 224 is selected from ZnO, Zn_{y1}Mg_{y2}O, Znₓ₁Alₓ₂O, and Znₐ₁Mgₐ₂Liₐ₃O, wherein x1, x2, y1, y2, a1, a2, and a3 are satisfied with: y1+y2=1, x1+x2=1, a1+a2+a3=1. In this embodiment, the material of the first electron transport layer 224 is Zn_{0.95}Mg_{0.05}O.

In an embodiment, the material of the first electron transport layer 224 may be Zn_{0.98}Al_{0.02}O, Zn_{0.9}Mg_{0.05}Li_{0.05}O, Zn_{0.9}Mg_{0.10}, Zn_{0.88}Mg_{0.12}O, or the like.

In an embodiment, the first electron transport layer 224 has a thickness h₁ ranging from 20 nm to 60 nm. Specifically, the thickness h₁ of the first electron transport layer 224 may be 21 nm, 22 nm, 30 nm, 38 nm, 45 nm, 48 nm, 58 nm, 60 nm, or the like. In the present embodiment, the thickness h₁ of the first electron transport layer 224 is 45 nanometers.

In an embodiment, the display panel 10 further includes a first transparent conductive layer 300. The first transparent conductive layer 300 is disposed on a side of the first electron transport layer 224 away from the substrate 110.

In an embodiment, the material of the first transparent conductive layer 300 is selected from indium tin oxide, indium zinc oxide, zinc aluminum oxide, and indium gallium zinc oxide. In the present embodiment, the material of the first transparent conductive layer 300 is indium gallium zinc oxide.

In an embodiment, the first transparent conductive layer 300 has a thickness R₁ ranging from 50 nm to 1000 nm. Specifically, the thickness R₁ of the first transparent conductive layer 300 may be 60 nm, 600 nm, 800 nm, 950 nm, 1000 nm, or the like. In this embodiment, the thickness R₁ of the first transparent conductive layer 300 is 600 nm.

The second light-emitting unit 230 includes a second hole injection layer 231, a second hole transport layer 232, a second light-emitting layer 233, and a second electron transport layer 234, which are sequentially stacked on the first transparent conductive layer 300.

In an embodiment, the second hole injection layer 231 material is selected from polyaniline, poly(3,4-ethylenedioxythiophene): polystyrene sulfonate, and polythiophene. In this embodiment, the material of the second hole injection layer 231 is polystyrene sulfonate.

In an embodiment, the second hole injection layer 231 has a thickness Y₂ ranging from 15 nm to 50 nm. Specifically, the thickness Y₂ of the second hole injection layer 231 may be 15 nm, 18 nm, 30 nm, 36 nm, 38 nm, 46 nm, 48 nm, 50 nm, or the like. In this embodiment, the thickness Y₂ of the second hole injection layer 231 is 48 nm.

The first electron transport layer 224, the first transparent conductive layer 300, and the second hole injection layer 231 define a first charge layer 400 of the light-emitting structure 200. The first charge layer 400 is configured to provide electrons and holes required for the light-emitting structure 200.

In the present application, the first charge layer 400 is defined by the first electron transport layer 224, the first transparent conductive layer 300, and the second hole injection layer 231. Since the first transparent conductive layer 300 is in form of a N-type semiconductor, and the second hole injection layer 231 is in form of a P-type semiconductor, as such, the first transparent conductive layer 300 and the second hole injection layer 231 together define a P-N junction. With the conduction band of the first transparent conductive layer 300 equal to or less than the highest occupied molecular orbital (HOMO) of the second hole injection layer 231, when an external electric field is applied, electrons and holes are generated at the P-N junction, electrons are injected into the light-emitting unit through the first transparent conductive layer 300, and the holes are injected into another light-emitting unit. That is, the first charge layer 400 can generate enough electrons and holes, thereby avoiding a problem of energy transfer caused by the stacked arrangement of the light-emitting layers of the display panel 10, and further avoiding a problem of uneven display of the white display panel 10. Further, the stability of the white display panel 10 is improved.

In an embodiment, the material of the second hole transport layer 232 is one or more of 4,4′,4″-tris(carbazol-9-yl)triphenylamine, poly(N,N′-bis(4-butylphenyl)-N,N′-bis(phenyl)-benzidine), poly(9,9-dioctylfluorene-co-N-(4-butylphenyl)diphenylamine), polyvinylcarbazole, and 4,4′-bis(9-carbazole)biphenyl. In this embodiment, the material of the second hole transport layer 232 is polyvinylcarbazole.

In an embodiment, the second hole transport layer 232 has a thickness D₂ ranging from 15 nm to 40 nm. Specifically, the thickness D₂ of the second hole transport layer 232 may be 15 nm, 18 nm, 30 nm, 33 nm, 36 nm, 40 nm, or the like. In this embodiment, the thickness D₂ of the second hole transport layer 232 is 20 nm.

In an embodiment, the material of the second light-emitting layer 233 is a core-shell structure in which a shell layer covers a core layer. The material of the core layer includes one of CdZnSe, ZnSe, InP, and CdSe. The material of the shell layer includes one or a combination of CdS and ZnS. In this embodiment, the material of the core layer is CdZnSe, and the material of the shell layer is CdS.

In an embodiment, the second light-emitting layer 233 includes one of a green light-emitting layer, a red light-emitting layer, and a blue light-emitting layer. In this embodiment, the second light-emitting layer 233 is a green light-emitting layer, that is, the second light-emitting unit 230 is a green light-emitting unit.

In an embodiment, the material of the second light-emitting layer 233 has a particle diameter ranging from 3 nm to 6 nm. In this embodiment, the material of the second light-emitting layer 233 has a particle diameter of 4 nm.

In an embodiment, the material of the second light-emitting layer 233 the has a photoluminescence wavelength ranging from 535 nm to 555 nm.

In the present application, the material of the core layer is CdZnSe, the material of the shell layer is CdS, and the particle diameter of the material of the second light-emitting layer 233 ranges from 3 nm to 6 nm, as such, the second light-emitting layer 233 emits green lights.

In an embodiment, the second light-emitting layer 233 has a thickness T₂ ranging from 10 nm to 40 nm. Specifically, the thickness T₂ of the second light-emitting layer 233 may be 10 nm, 18 nm, 30 nm, 36 nm, 38 nm, 38 nm, 40 nm, or the like. In this embodiment, the thickness T₂ of the second light-emitting layer 233 is 20 nm.

In an embodiment, the material of the second electron transport layer 234 is selected from ZnO, Zn_{y1}Mg_{y2}O, Znₓ₁Alₓ₂O, and Znₐ₁Mgₐ₂Liₐ₃O, wherein x1, x2, y1, y2, a1, a2, and a3 are satisfied with: y1+y2=1, x1+x2=1, a1+a2+a3=1. In this embodiment, the material of the second electron transport layer 234 is Zn_{0.95}Mg_{0.05}O.

In an embodiment, the material of the second electron transport layer 234 may be Zn_{0.98}Al_{0.02}O, Zn_{0.9}Mg_{0.05}Li_{0.05}O, Zn_{0.9}Mg_{0.1}O, Zn_{0.88}Mg_{0.12}O, or the like.

In an embodiment, the second electron transport layer 234 has a thickness h₂ ranging from 20 nm to 60 nm. Specifically, the thickness h₂ of the second electron transport layer 234 may be 21 nm, 22 nm, 30 nm, 38 nm, 45 nm, 48 nm, 58 nm, or 60 nm. In this embodiment, the thickness h₂ of the second electron transport layer 234 is 38 nm.

In an embodiment, the display panel 10 further includes a second transparent conductive layer 500. A second transparent conductive layer 500 is provided on a side of the second electron transport layer 234 away from the substrate 110.

In an embodiment, the material of the second transparent conductive layer 500 is selected from indium tin oxide, indium zinc oxide, zinc aluminum oxide, and indium gallium zinc oxide. In this embodiment, the material of the second transparent conductive layer 500 is indium zinc oxide.

In an embodiment, the second transparent conductive layer 500 has a thickness R₂ ranging from 50 nm to 1000 nm. Specifically, the thickness R₂ of the second transparent conductive layer 500 may be 60 nm, 600 nm, 800 nm, 950 nm, or 1000 nm. The thickness R₂ of the second transparent conductive layer 500 is 500 nm.

The third light-emitting unit 240 includes a third hole injection layer 241, a third hole transport layer 242, a third light-emitting layer 243, and a third electron transport layer 244, which are sequentially stacked on the second transparent conductive layer 500.

In an embodiment, the material of the third hole injection layer 241 is selected from polyaniline, poly(3,4-ethylenedioxythiophene): polystyrene sulfonate, and polythiophene. In this embodiment, the material of the third hole injection layer 241 is polythiophene.

In an embodiment, the third hole injection layer 241 has a thickness Y₃ ranging from 15 nm to 50 nm. Specifically, the thickness Y₃ of the third hole injection layer 241 may be 15 nm, 18 nm, 30 nm, 36 nm, 38 nm, 46 nm, 48 nm, or 50 nm. In this embodiment, the thickness Y₃ of the third hole injection layer 241 is 45 nm.

The second electron transport layer 234, the second transparent conductive layer 500, and the third hole injection layer 241 define a second charge layer 600 of the light-emitting structure 200. The second charge layer 600 is configured to provide electrons and holes required for the light-emitting structure 200.

In the present application, the second charge layer 600 is defined by the second electron transport layer 234, the second transparent conductive layer 500, and the third hole injection layer 241. Since the second transparent conductive layer 500 is in form of a N-type semiconductor, and the third hole injection layer 241 is in form of a P-type semiconductor, the second transparent conductive layer 500 and the third hole injection layer 241 together define a P-N junction. With the conduction band of the second transparent conductive layer 500 equal to or less than the highest occupied molecular orbital (HOMO) of the third hole injection layer 241, when an external electric field is applied, electrons and holes are generated at the P-N junction, electrons are injected into the light-emitting unit through the second transparent conductive layer 500, and the holes are injected into another light-emitting unit. That is, the second charge layer 600 can generate enough electrons and holes, thereby avoiding a problem of energy transfer caused by the stacked arrangement of the light-emitting layers of the display panel 10, and further avoiding a problem of uneven display of the white display panel 10. Further, the stability of the white display panel 10 is improved.

In an embodiment, the material of the third hole transport layer 242 includes one or more of 4,4′,4″-tris(carbazol-9-yl)triphenylamine, poly(N,N′-bis(4-butylphenyl)-N,N′-bis(phenyl)-benzidine), poly(9,9-dioctylfluorene-co-N-(4-butylphenyl)diphenylamine), polyvinylcarbazole, and 4,4′-bis(9-carbazole)biphenyl. In this example, the material of the third hole transport layer 242 is poly(N,N′-bis(4-butylphenyl)-N,N′-bis(phenyl)-benzidine).

In an embodiment, the third hole transport layer 242 has a thickness D₃ ranging from 15 nm to 40 nm. Specifically, the thickness D₃ of the third hole transport layer 242 may be 15 nm, 18 nm, 30 nm, 33 nm, 36 nm, or 40 nm. In this embodiment, the thickness D₃ of the third hole transport layer 242 is 18 nm.

In an embodiment, the material of the third light-emitting layer 243 is a core-shell structure in which a shell layer covers a core layer. The material of the core layer includes one of CdZnSe, ZnSe, InP, and CdSe. The material of the shell layer includes one or a combination of CdS and ZnS. In this embodiment, the material of the core layer is ZnSe, and the material of the shell layer is a combination of CdS and ZnS.

In an embodiment, the third light-emitting layer 243 includes one of a red light-emitting layer, a green light-emitting layer, and a blue light-emitting layer. In this embodiment, the third light-emitting layer 243 is a red light-emitting layer. That is, the third light-emitting unit 240 is a red light-emitting unit.

In the present application, the blue light-emitting unit, the green light-emitting unit, and the red light-emitting unit are stacked to define the light-emitting structure 200, so that the display panel 10 emits white lights.

In an embodiment, the material of the third light-emitting layer 243 has a particle diameter ranging from 7 nm to 8 nm. In this embodiment, the material of the third light-emitting layer 243 has a particle diameter of 8 nm.

In an embodiment, the material of the third light-emitting layer 243 has a photoluminescence wavelength ranging from 615 nm to 625 nm.

In an embodiment, the third light-emitting layer 243 has a thickness T₃ ranging from 10 nm to 40 nm. Specifically, the thickness T₃ of the third light-emitting layer 243 may be 10 nm, 18 nm, 30 nm, 36 nm, 38 nm, 46 nm, or 40 nm. In this embodiment, the thickness T₃ of the third light-emitting layer 243 is 22 nm.

In the present application, the material of the core layer is ZnSe, the material of the shell layer is a combination of CdS and ZnS, and the particle diameter of the martial of the third light-emitting layer 243 ranges from 7 nm to 8 nm, so that the third light-emitting layer 243 emits red lights.

In an embodiment, the material of the third electron transport layer 244 is selected from ZnO, Zn_{y1}Mg_{y2}O, Znₓ₁Alₓ₂O, and Znₐ₁Mgₐ₂Liₐ₃O, wherein x1, x2, y1, y2, a1, a2, and a3 are satisfied with: y1+y2=1, x1+x2=1, a1+a2+a3=1. In this embodiment, the material of the third electron transport layer 244 is Zn_{0.85}Mg_{0.05}Li_{0.1}O.

In an embodiment, the material of the third electron transport layer 244 may be Zn_{0.98}Al_{0.02}O, Zn_{0.9}Mg_{0.05}Li_{0.05}O, Zn_{0.9}Mg_{0.1}O, Zn_{0.88}Mg_{0.12}O, or the like.

In an embodiment, the third electron transport layer 244 has a thickness h₃ ranging from 20 nm to 60 nm. Specifically, the thickness h₃ of the third electron transport layer 244 may be 21 nm, 22 nm, 30 nm, 38 nm, 45 nm, 48 nm, 58 nm, or 60 nm. In this embodiment, the thickness h₃ of the third electron transport layer 244 is 30 nm.

In an embodiment, the light-emitting structure 200 further includes a second electrode layer 250. The second electrode layer 250 is disposed on a side of the third electron transport layer 244 away from the substrate 110.

In an embodiment, the material of the second electrode layer 250 includes gold, silver, aluminum, alloys thereof, and the like. In this embodiment, the material of the second electrode layer 250 is gold.

In an embodiment, the second electrode layer 250 has a thickness H₂ ranging from 80 nm to 500 nm. Specifically, the thickness H₂ of the second electrode layer 250 may be 90 nm, 200 nm, 340 nm, 460 nm, or 500 nm. In this embodiment, the thickness H₂ of the second electrode layer 250 is 400 nm. The second electrode layer 250 is an anode or a cathode, and in this embodiment, the second electrode layer 250 is a cathode.

In the present application, the display panel 10 may be a white quantum dot light-emitting diode display panel or a white organic light-emitting diode display panel. The white display panel 10 may be a photoluminescence display panel.

An embodiment of the present application discloses a display panel 10 including an array substrate 100 and a light-emitting structure 200. The array substrate 100 includes a substrate 110, and a transistor layer 120 disposed on the substrate 110. The array substrate 100 further includes a light-converting layer 130 in which red light-emitting particles 131 are doped. The light-emitting structure 200 is disposed on the array substrate 100, and the light-emitting structure 200 emitting white lights. In the present application, by doping the light-converting layer 130 with the red light-emitting particles 131, the light-converting layer 130 can be used as an organic flat layer of the white display panel 10 while functioning to convert other light lights into red light lights, thereby increasing the amount or proportion of the red light lights. Thus, the color rendering index of the white display panel 10 is improved, and further the performance of the white display panel 10 is improved.

Referring to FIG. 2, FIG. 2 is a schematic diagram of a second structure of a display panel according to an embodiment of the present application. It should be noted that the second structure may differ from the first structure in the followings.

The light-converting layer 130 is disposed on a side of the substrate 110 away from the light-emitting structure 200. The material of the light-converting layer 130 is selected from polyimide, polymethyl methacrylate, silicone resin, and epoxy resin. In this embodiment, the material of the light-converting layer 130 is polyimide.

In an embodiment, the display panel 10 further includes an organic flat layer 140. The organic flat layer 140 is disposed between the transistor layer 120 and the light-emitting structure 200. The organic flat layer 140 is used for flatting the film layers in the transistor layer 120 to avoid breakage or damage to the film layers in the transistor layer 120 during subsequent process or use, thereby improving the performance of the white display panel 10.

In the present application, the light-converting layer 130 is disposed on the side of the substrate 110 away from the light-emitting structure 200, so that the light-converting layer 130 can be used as a buffer layer in the display panel 10 while performing the light convert. As such, the buffer layer can function to convert lights. Thus, the film layers in the display panel 10 are protected, and the color rendering index of the white display panel 10 is improved, thereby improving the performance of the white display panel 10.

In an embodiment, the display panel 10 further includes a protective layer. The protective layer is provided on a side of the light-converting layer 130 away from the light-emitting structure 200.

In an embodiment, the protective layer includes an organic protective layer and an inorganic protective layer. The material of the organic protective layer is selected from polycarbonate, polyimide and polymethyl methacrylate. The material of the inorganic protective layer is selected from silicon dioxide, silicon nitride, silicon oxynitride, and aluminum trioxide.

In the present application, the protective layer is provided on the side of the light-converting layer 130 away from the substrate 110, to avoid the influence of the external environment (such as humidity, oxygen, light, ozone, and the like) on the light-converting layer 130. Thus, the stability of the color rendering index of the white display panel 10 is improved, and the performance of the white display panel 10 is improved.

In an embodiment, the protective layer may be formed by disposing a plurality of the organic protective layers and a plurality of the inorganic protective layer alternatively in a one-by-one manner. In the application, the protective layer is defined by a plurality of organic protective layers and a plurality of inorganic protective layers, so that the influence of the external environment on the light-converting layer 130 is further avoided, the stability of the color rendering index of the white display panel 10 is improved, and the performance of the white display panel 10 is improved.

Referring to FIG. 3, FIG. 3 is a schematic diagram of a third structure of a display panel according to an embodiment of the present application. It should be noted that the third structure may differ from the first structure in the followings.

The light-converting layer 130 is formed by red light-emitting particles 131. The light-converting layer 130 does not contain materials such as polyimide, polymethyl methacrylate, silicone resin, and epoxy resin. The white display panel 10 further includes an organic flat layer 140. The light-converting layer 130 is disposed between the organic flat layer 140 and the first electrode layer 210, or the light-converting layer 130 is disposed between the transistor layer 120 and the organic flat layer 140.

It should be noted that only a few red light-emitting particles 131 are shown in the drawings, but a simple schematic illustration does not imply that the light-converting layer 130 contains other materials.

In an embodiment, the organic flat layer 140 is selected from polyimides, polymethyl methacrylate, silicone resins, and epoxy resins.

In an embodiment, the light-converting layer 130 has a thickness W₁ ranging from 20 nm to 200 nm. Specifically, the thickness W₁ of the light-converting layer 130 is 25 nm, 50 nm, 90 nm, 160 nm, 180 nm, 190 nm, or the like.

In the present application, by providing the light-converting layer 130 with the thickness W₁ ranging from 20 nm to 200 nm, the conversion efficiency of the light-converting layer 130 is improved and the display performance of the white display panel 10 is not affected. In a case that the thickness W₁ of the light-converting layer 130 is provided less than 20 nm, the light-converting layer 130 is too thin to have a high light-converting efficiency, and the color rendering index of the white display panel 10 is affected. In a case that the thickness W₁ of the light-converting layer 130 is provided greater than 200 nm, the light-converting layer 130 convert all of other lights into red lights, so that white lights cannot be generated, thereby affecting the performance of the white display panel 10.

The present application provides a display panel, wherein a light-converting layer 130 is formed by red light-emitting particles 131. The light-converting layer 130 only functions to convert lights, and an organic flat layer is provided to flatten another structure in the array substrate 100, thereby improving the light-converting effect of the light-converting layer 130, and further improving the color rendering index of the white display panel 10.

Referring to FIG. 4, FIG. 4 is a schematic diagram of a third structure of a display panel according to an embodiment of the present application. It should be noted that the fourth structure differs from the second structure in the followings.

The light-converting layer 130 is formed by red light-emitting particles 131. The light-converting layer 130 does not contain materials such as polyimide, polymethyl methacrylate, silicone resin, and epoxy resin. The light-converting layer 130 is disposed on a side of the substrate 110 away from the light-emitting structure 200.

In the present application, the light-converting layer 130 is provided on the side of the substrate 110 away from the light-emitting structure 200, and the light-converting layer 130 is formed by only the red light-emitting particles 131. That is, the light-converting layer 130 has only the light-converting effect, thereby improving the color rendering index of the white display panel 10, and further improving the display performance of the white display panel 10.

It should be noted that only a few red light-emitting particles 131 are shown in the drawings, but a simple schematic illustration does not imply that the light-converting layer 130 contains other materials.

In an embodiment, the light-converting layer 130 has a thickness W₁ ranging from 20 nm to 200 nm. Specifically, the thickness W₁ of the light-converting layer 130 is 25 nm, 50 nm, 90 nm, 160 nm, 180 nm, 190 nm, or the like.

In the present application, by providing the light-converting layer 130 with the thickness W₁ ranging from 20 nm to 200 nm, the conversion efficiency of the light-converting layer 130 is improved and the display performance of the white display panel 10 is not affected. In a case that the thickness W₁ of the light-converting layer 130 is provided less than 20 nm, the light-converting layer 130 is too thin to have a high light-converting efficiency, and the color rendering index of the white display panel 10 is affected. In a case that the thickness W₁ of the light-converting layer 130 is provided greater than 200 nm, the light-converting layer 130 convert all of other lights into red lights, so that white lights cannot be generated, thereby affecting the performance of the white display panel 10.

In an embodiment, the white display panel 10 further includes an organic flat layer 140. The organic flat layer 140 is disposed between the transistor layer 120 and the first electrode layer 210. The organic flat layer 140 is configured to flatten the film layers in the flat transistor layer 120, to avoid breakage or damage to the film layers in the transistor layer 120 during subsequent process or use, thereby improving the performance of the white display panel 10.

In an embodiment, the organic flat layer 140 is selected from polyimides, polymethyl methacrylate, silicone resins, and epoxy resins.

In an embodiment, the display panel 10 further includes a protective layer. The protective layer is provided on a side of the light-converting layer 130 away from the light-emitting structure 200.

In an embodiment, the protective layer includes an organic protective layer and an inorganic protective layer. The material of the organic protective layer is selected from polycarbonate, polyimide and polymethyl methacrylate. The material of the inorganic protective layer is selected from silicon dioxide, silicon nitride, silicon oxynitride, and aluminum trioxide.

In the present application, the protective layer is provided on the side of the light-converting layer 130 away from the substrate 110, to avoid the influence of the external environment (such as humidity, oxygen, light, ozone, and the like) on the light-converting layer 130. Thus, the stability of the color rendering index of the white display panel 10 is improved, and the performance of the white display panel 10 is improved.

In an embodiment, the protective layer may be formed by disposing a plurality of the organic protective layers and a plurality of the inorganic protective layer alternatively in a one-by-one manner. In the application, the protective layer is defined by a plurality of organic protective layers and a plurality of inorganic protective layers, so that the influence of the external environment on the light-converting layer 130 is further avoided, the stability of the color rendering index of the white display panel 10 is improved, and the performance of the white display panel 10 is improved.

The present application provides a display panel, wherein a light-converting layer 130 is formed by red light-emitting particles 131. The light-converting layer 130 only functions to convert lights, and an organic flat layer is provided to flatten another structure in the array substrate 100, thereby improving the light-converting effect of the light-converting layer 130, and further improving the color rendering index of the white display panel 10.

An embodiment of the present application discloses a display panel 10. The display panel 10 includes an array substrate 100 and a light-emitting structure 200. The array substrate 100 includes a light-converting layer 130. The light-converting layer 130 is configured to convert other lights into red lights. The light-emitting structure 200 is disposed on the array substrate 100, and the light-emitting structure 200 emits white lights. In the present application, by providing the light-converting layer 130, the color rendering index of the white display panel 10 is improved, and the performance of the white display panel 10 is improved.

A display panel provided by the present application is described in details, and the principles and embodiments of the present application are described with reference to specific examples. The description of the above examples is merely provided to help understand the method and the core idea of the present application. At the same time, variations to the detailed embodiments and the scope of application will occur to those skilled in the art in accordance with the teachings of the present application. In view of the foregoing, the present description should not be construed as limiting the application.

1. A display panel, comprising:
an array substrate, wherein the array substrate comprises a light-converting layer, and the light-converting layer is configured to convert other lights into red light; and
a light-emitting structure disposed on the array substrate, wherein the light-emitting structure emits white lights.

2. The display panel of claim 1, wherein the array substrate further comprises a substrate, and a transistor layer disposed on the substrate; wherein the light-converting layer is doped with red light-emitting particles, and the light-converting layer is disposed between the transistor layer and the light-emitting structure.

3. The display panel of claim 2, wherein doping concentration of the red light-emitting particles in the light-converting layer ranges from 5% to 35%.

4. The display panel of claim 3, wherein each of the red light-emitting particles is in a shell-coated structure, and a shell layer of the shell-coated structure covers a core layer of the shell-coated structure.

5. The display panel of claim 4, wherein a material of the core layer comprises at least one of CdSe, CdZnSe, InP, and ZnSe.

6. The display panel of claim 5, wherein a material of the shell layer comprises at least one of CdS and ZnS.

7. The display panel of claim 1, wherein the array substrate further comprises a substrate, the light-emitting structure is disposed on the substrate, and the light-converting layer is disposed on a side of the substrate away from the light-emitting structure.

8. The display panel of claim 7, wherein the display panel further comprises a protective layer, and the protective layer is disposed on a side of the light-converting layer away from the light-emitting structure.

9. The display panel of claim 1, wherein the light-converting layer has a thickness ranging from 50 nm to 3000 nm.

10. The display panel of claim 2, wherein each of the red light-emitting particles has a particle diameter ranging from 7 nm to 8 nm.

11. The display panel of claim 2, wherein a material of the light-converting layer is selected from polyimide, polymethyl methacrylate, silicone resin, and epoxy resin.

12. The display panel of claim 1, wherein the light-emitting structure comprises a first light-emitting unit, a second light-emitting unit, and a third light-emitting unit sequentially stacked; wherein the first light-emitting unit, the second light-emitting unit, and the third light-emitting unit comprise a red light-emitting unit, a blue light-emitting unit, and a green light-emitting unit; wherein the first light-emitting unit, the second light-emitting unit, and the third light-emitting unit emit lights of different colors respectively.

13. The display panel of claim 12, wherein the display panel further comprises a first transparent conductive layer and a second transparent conductive layer;
the light-emitting structure further comprises a first electrode layer and a second electrode layer;
the first light-emitting unit comprises a first hole injection layer, a first hole transport layer, a first light-emitting layer, and a first electron transport layer sequentially stacked on the first electrode layer;
the second light-emitting unit comprises a second hole injection layer, a second hole transport layer, a second light-emitting layer, and a second electron transport layer sequentially stacked on the first transparent conductive layer;
the third light-emitting unit comprises a third hole injection layer, a third hole transport layer, a third light-emitting layer, and a third electron transport layer sequentially stacked on the second transparent conductive layer; and
the second electrode layer is disposed on a side of the third electron transport layer away from the substrate.

14. The display panel of claim 13, wherein a material each of the first light-emitting layer, the second light-emitting layer, and the third light-emitting layer has a core-shell structure, and a shell layer of the core-shell structure covers a core layer of the core-shell structure, wherein a material of the core layer comprises one of CdZnSe, ZnSe, InP, and CdSe, and a material of the shell layer comprises one or a combination of CdS and ZnS.

15. The display panel of claim 13, wherein materials of the first transport layer, the second electron transport layer, and the third electron transport layer comprise at least one of Zn_{0.98}Al_{0.02}O, Zn_{0.9}Mg_{0.05}Li_{0.05}O, Zn_{0.9}Mg_{0.1}O, and Zn_{0.88}Mg_{0.12}O.

16. The display panel of claim 2, wherein the display panel further comprises a first electrode layer, the transistor layer is disposed on the substrate, the light-converting layer is disposed on the transistor layer, the first electrode layer is disposed on the light-converting layer, and the light-emitting structure is disposed on the first electrode layer.

17. The display panel of claim 16, wherein the display panel further comprises an organic flat layer, and the organic flat layer is disposed between the light-converting layer and the first electrode layer.

18. The display panel of claim 8, wherein the display panel further comprises an organic flat layer and a first electrode layer, the light-converting layer is disposed on the protective layer, the substrate is disposed on the light-converting layer, the transistor layer is disposed on the substrate, the organic flat layer is disposed on the transistor layer, the first electrode layer is disposed on the organic flat layer, and the light-emitting structure is disposed on the first electrode layer.

19. The display panel of claim 8, wherein the display panel further comprises an organic flat layer and a first electrode layer, the light-converting layer is disposed on the protective layer, the substrate is disposed on the light-converting layer, the transistor layer is disposed on the substrate, the organic flat layer is disposed on the transistor layer, the first electrode layer is disposed on the organic flat layer, and the light-emitting structure is disposed on the first electrode layer.

20. The display panel of claim 8, wherein the protective layer comprises an organic protective layer and an inorganic protective layer, a material of the organic protective layer is selected from polycarbonate, polyimide, and polymethyl methacrylate; and a material of the inorganic protective layer is selected from silicon dioxide, silicon nitride, silicon oxynitride, and aluminum trioxide.
